(19) United States
(12) Patent Application Publication
(10) Pub. No.: US 2024/0304537 A1
(43) Pub. Date: Sep. 12, 2024

(54) ELECTRONIC DEVICE

(71) Applicant: FUJI ELECTRIC CO., LTD., Kawasaki-shi (JP)

(72) Inventors: Motohito HORI, Matsumoto-city (JP); Yoshinari IKEDA, Matsumoto-city (JP); Akira HIRAO, Matsumoto-city (JP)

(73) Assignee: FUJI ELECTRIC CO., LTD., Kawasaki-shi (JP)

(21) Appl. No.: 18/584,148

(22) Filed: Feb. 22, 2024

(30) Foreign Application Priority Data
Mar. 8, 2023 (JP) 2023-035672

(51) Int. Cl. H01L 23/498; H01L 23/00; H01L 23/367; H01L 25/00; H01L 25/07

(52) U.S. Cl. CPC H01L 23/49844; H01L 23/49822; H01L 24/30; H01L 24/32; H01L 25/072; H01L 25/50; H01L 23/367; H01L 2224/3003; H01L 2224/32225; H01L 2924/13091

(57) ABSTRACT

An electronic device, including: a conductive element having a conductive region on a front surface thereof; a fixing element having a fixing region on a front surface thereof, the fixing element being located apart from the conductive element in a plan view of the electronic device; and a wiring member having a flat plate shape. The wiring member includes a first portion bonded to the conductive region of the conductive element, a second portion fixed to the fixing region of the fixing element, and an inclined portion between the first portion and the second portion, the inclined portion being elastically deformable. In a side view of the electronic device, the conductive region of the conductive element and the fixing region of the fixing element are at different heights in a thickness direction of the electronic device.

### CROSS-REFERENCE TO RELATED APPLICATION

This application is based upon and claims the benefit of priority of the prior Japanese Patent Application No. 2023-035672, filed on Mar. 8, 2023, the entire contents of which are incorporated herein by reference.

### BACKGROUND OF THE INVENTION

### 1. Field of the Invention

The embodiments discussed herein relate to an electronic device.

### 2. Background of the Related Art

For example, there is a semiconductor device that includes a heat dissipating substrate, an insulating substrate arranged on the heat dissipating substrate and having a wiring layer, a plurality of semiconductor elements arranged on the insulating substrate, a conductive block electrically connected to front surface electrodes of the semiconductor elements, and a terminal electrode. The conductive block has a convex portion, which is bonded to the insulating substrate (see, for example, International Publication Pamphlet No. WO 2016/152258). Further, there is another semiconductor device that includes a semiconductor chip having a first electrode on a first surface thereof, a metal plate, and a first conductive bonding sheet that is disposed between the first surface of the semiconductor chip and the metal plate and bonds the first electrode to the metal plate (see, for example, Japanese Laid-open Patent Publication No. 2022-053224). Still further, there is another semiconductor device in which a semiconductor supporting metal plate is provided with legs. This prevents a deterioration in parallelism and a displacement between the semiconductor supporting metal plate and a lead frame circuit board and achieves an electrical connection between the semiconductor supporting metal plate and the lead frame circuit board (see, for example, Japanese Laid-open Patent Publication No. 2004-221460). Still further, there is yet another semiconductor device that includes a semiconductor element disposed on the top surface of a circuit board, a metal wiring board disposed on the top surface of the semiconductor element, and a temperature sensor disposed on the top surface of the metal wiring board. In this semiconductor device, a notch part formed in the metal wiring board blocks heat transferred from the semiconductor element, which improves the accuracy of detecting the temperature of the semiconductor element (see, for example, Japanese Laid-open Patent Publication No. 2021-064707).

### SUMMARY OF THE INVENTION

According to one aspect, there is provided an electronic device, including a conductive element having a conductive region on a front surface thereof; a fixing element having a fixing region on an outside surface thereof, the fixing element being located apart from the conductive element in a plan view of the electronic device; and a wiring member having a flat plate shape, the wiring member including: a first portion bonded to the conductive region of the conductive element, a second portion fixed to the fixing region of the fixing element, and an inclined portion between the first portion and the second portion, the inclined portion being elastically deformable, wherein in a side view of the electronic device, the conductive region of the conductive element and the fixing region of the fixing element are at different heights in a thickness direction of the electronic device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a sectional view of the semiconductor device according to the first embodiment;

FIG. 3 is a flowchart illustrating a semiconductor device manufacturing method according to the first embodiment;

FIG. 4 is a plan view depicting a semiconductor chip bonding step included in the semiconductor device manufacturing method according to the first embodiment;

FIG. 5 is a sectional view depicting the semiconductor chip bonding step included in the semiconductor device manufacturing method according to the first embodiment;

FIG. 6 is a sectional view of a semiconductor device according to a reference example;

FIG. 7 is a graph representing stress applied to a lead frame of the reference example and the elasticity of the lead frame with respect to the thickness of the lead frame;

FIG. 8 is a sectional view of a semiconductor device according to a second embodiment;

FIG. 9 is a plan view of a semiconductor device according to a third embodiment;

FIG. 10 is a sectional view of the semiconductor device according to the third embodiment;

FIG. 11 is a plan view of a semiconductor device according to a fourth embodiment;

FIG. 12 is a plan view of a semiconductor unit provided in the semiconductor device according to the fourth embodiment; and

FIG. 13 is a sectional view illustrating a main part of the semiconductor device according to the fourth embodiment.

### DETAILED DESCRIPTION OF THE INVENTION

Hereinafter, embodiments will be described with reference to the accompanying drawings. In the following description, the terms “front surface” and “top surface” refer to an X-Y plane facing up (in the +Z direction) in a semiconductor device 1 illustrated in drawings. Similarly, the term “up” refers to an upward direction (the +Z direction) in the semiconductor device 1 illustrated in the drawings. The terms “rear surface” and “bottom surface” refer to an X-Y plane facing down (in the −Z direction) in the semiconductor device 1 illustrated in the drawings. Similarly, the term “down” refers to a downward direction (the −Z direction) in the semiconductor device 1 illustrated in the drawings. The same directionality applies to other drawings, as appropriate. The expression “located higher” indicates a higher position (in the +Z direction) in the semiconductor device 1 illustrated in the drawings. Similarly, the expression “located lower” indicates a lower position (in the −Z direction) in the semiconductor device 1 illustrated in the drawings. The terms “front surface,” “top surface,” “up,” “rear surface,” “bottom surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately equal” may allow an error range of ±10%. In addition, the expressions “being perpendicular,” “being orthogonal,” and “being parallel” may allow an error range of ±10%. In addition, the following describes the semiconductor device 1 as an example of an electronic device. The semiconductor device 1 is just an example of an electronic device, and electronic devices are not limited to the semiconductor device 1.

### First Embodiment

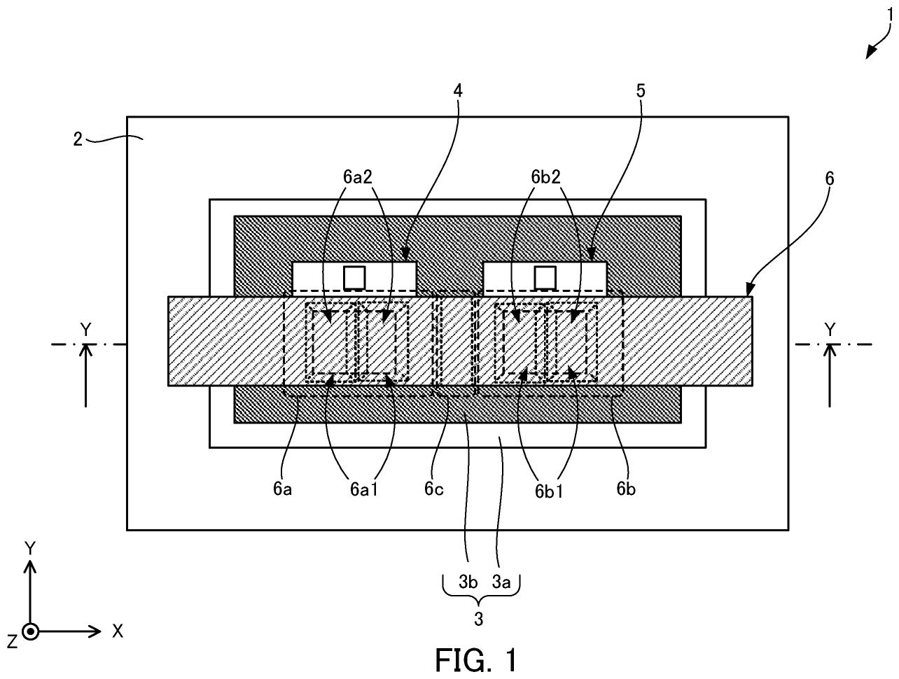

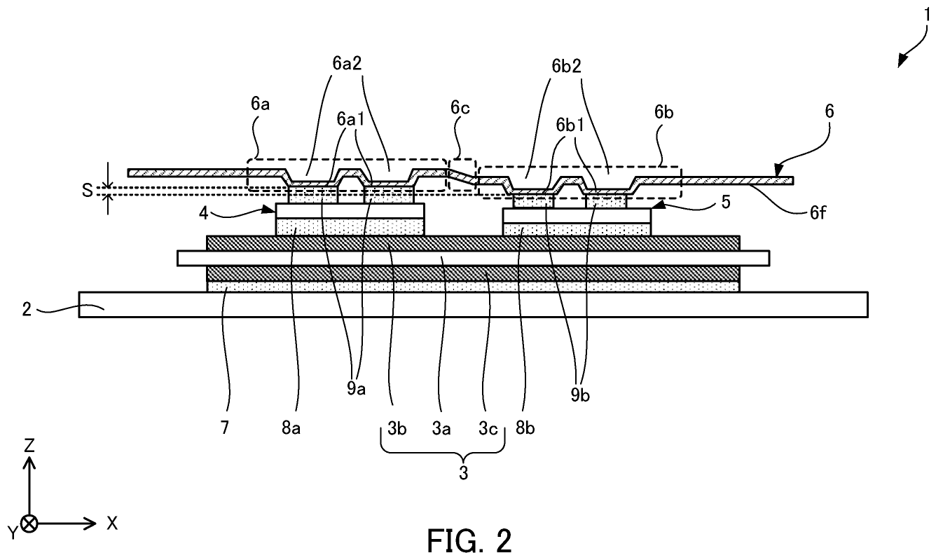

A semiconductor device according to a first embodiment will be described with reference to FIGS. 1 and 2. FIG. 1 is a plan view of a semiconductor device according to the first embodiment, and FIG. 2 is a sectional view of the semiconductor device according to the first embodiment. In this connection, FIG. 2 is a sectional view taken along a dash-dotted line Y-Y of FIG. 1.

The semiconductor device 1 may include at least a heat dissipation base 2, an insulated circuit substrate 3, semiconductor chips 4 and 5, and a lead frame 6. In addition to these, the semiconductor device 1 may include a case and external connection terminals, for example.

The heat dissipation base 2 is rectangular in plan view and has a flat plate shape, for example. In addition, the corners of the heat dissipation base 2 may be chamfered or rounded, for example. The heat dissipation base 2 is made of a metal with high thermal conductivity as a main component. Examples of the metal here include copper, aluminum, and an alloy containing at least one of these. The heat dissipation base 2 may be plated in order to improve its corrosion resistance. Examples of the plating material used here include nickel, a nickel-phosphorus alloy, and a nickel-boron alloy.

The insulated circuit substrate 3 includes an insulating plate 3a, a conductive plate 3b formed on the front surface of the insulating plate 3a, and a metal plate 3c formed on the rear surface of the insulating plate 3a. The insulating plate 3a is rectangular in plan view. In addition, the insulating plate 3a may have smooth corners. For example, the corners of the insulating plate 3a may be chamfered or rounded. The insulating plate 3a may be made of ceramics or an insulating resin with high thermal conductivity. For example, the ceramics contain aluminum oxide, aluminum nitride, or silicon nitride as a main component. In addition, for example, the insulating resin may be a paper phenol substrate, a paper epoxy substrate, a glass composite substrate, or a glass epoxy substrate.

For example, the conductive plate 3b (conductive metal element) has a flat plate shape, is smaller in size than the insulating plate 3a, and is formed on the entire front surface of the insulating plate 3a except the edge thereof. The quantity and shape of the conductive plate 3b illustrated in FIGS. 1 and 2 are just an example. The quantity and shape of the conductive plate 3b may be set so as to form a predetermined circuit with semiconductor chips 4 and 5, which will be described later. The conductive plate 3b may be made of a metal with high electrical conductivity. Examples of the metal here include copper, aluminum, and an alloy containing at least one of these. Plating may be performed on the surface of the conductive plate 3b to improve its corrosion resistance. Examples of the plating material used here include nickel, a nickel-phosphorus alloy, and a nickel-boron alloy. The semiconductor chips 4 and 5 are electrically bonded to the front surface (conductive principal surface) of the conductive plate 3b.

The metal plate 3c is rectangular in plan view. The corners of the metal plate 3c may be chamfered or rounded, for example. The metal plate 3c is smaller in size than the insulating plate 3a, and is formed on the entire rear surface of the insulating plate 3a except the edge thereof. The metal plate 3c is made of a metal with high thermal conductivity as a main component. Examples of the metal here include copper, aluminum, and an alloy containing at least one of these. The metal plate 3c may be plated in order to improve its corrosion resistance. Examples of the plating material used here include nickel, a nickel-phosphorus alloy, and a nickel-boron alloy.

In the case where the insulating plate 3a is made of ceramics, a direct copper bonding (DCB) substrate or an active metal brazed (AMB) substrate may be used as the insulated circuit substrate 3 configured as above, for example. In the insulated circuit substrate 3, heat generated by the semiconductor chips 4 and 5 is transferred through the conductive plate 3b, insulating plate 3a, and metal plate 3c to the rear surface of the insulated circuit substrate 3. The heat transferred to the rear surface of the insulated circuit substrate 3 is dissipated from the heat dissipation base 2.

This insulated circuit substrate 3 is bonded to the heat dissipation base 2 via a bonding member 7. For example, the bonding member 7 is a solder, a brazing material, or a sintered metal. The solder may be a lead-free solder. For example, the lead-free solder contains, as a main component, an alloy containing at least two of tin, silver, copper, zinc, antimony, indium, and bismuth. In addition, the solder may contain an additive. Examples of the additive include nickel, germanium, cobalt, and silicon. The solder containing the additive exhibits improved wettability, gloss, and bond strength, which results in an improvement in the reliability. The brazing material contains, as a main component, at least one of an aluminum alloy, a titanium alloy, a magnesium alloy, a zirconium alloy, and a silicon alloy, for example. The insulated circuit substrate 3 may be bonded by brazing using such a bonding member. A material to be sintered into the sintered metal is powders of silver, iron, copper, aluminum, titanium, nickel, tungsten, molybdenum, or an alloy containing one of these, for example.

The semiconductor chip 4 (an example of a second semiconductor chip) and the semiconductor chip 5 (an example of a first semiconductor chip) may be power devices that are made of silicon. A power device may be provided with a switching function and a diode function. For example, a power device is a reverse conducting-insulated gate bipolar transistor (RC-IGBT). An RC-IGBT is an element in which an IGBT, which is a switching element, and a free-wheeling diode (FWD), which is a diode element, are integrated into one chip. For example, the semiconductor chips 4 and 5 of this type each have a collector electrode serving as an input electrode on the rear surface thereof and have a gate electrode serving as a control electrode 4b or 5b and an emitter electrode serving as an output electrode 4a (an example of a second upper electrode in a fixing region on the front surface that is an outside surface of the semiconductor chip) or 5a (an example of a first upper electrode in a conductive region) on the front surface thereof, as will be described later.

Alternatively, the semiconductor chips 4 and 5 may be power devices that are made of silicon carbide. An example of such a power device is a power metal-oxide-semiconductor field-effect transistor (MOSFET). The semiconductor chips 4 and 5 of this type each have a drain electrode serving as an input electrode on the rear surface thereof, and have a gate electrode serving as a control electrode 4b or 5b and a source electrode serving as an output electrode 4a or 5a on the front surface thereof.

The semiconductor chips 4 and 5 are bonded to the conductive plate 3b of the insulated circuit substrate 3 via bonding members 8a (an example of a second bonding member) and 8b (an example of a first bonding member). The bonding members 8a and 8b may be made of the same material as the bonding member 7. In this connection, the bonding members 8a and 8b may be a sintered metal.

In addition, the output electrodes 4a and 5a of the semiconductor chips 4 and 5 have different heights measured from the front surface of the conductive plate 3b of the insulated circuit substrate 3. Here, this difference in height is due to a difference in thickness between the bonding members 8a and 8b. In this connection, in the case where the semiconductor chips 4 and 5 are of different types, the semiconductor chips 4 and 5 may have different thicknesses. In the case where the semiconductor chips 4 and 5 have different thicknesses, the bonding members 8a and 8b may have the same thickness. In addition, in plan view, the output electrodes 4a and 5a of the semiconductor chips 4 and 5 are at least 5 mm apart from each other in the ±X directions.

The lead frame 6 (an example of a wiring member) has an elongated shape in plan view. The length (in the ±X directions) of the lead frame 6 may be greater than the length of the long side in the long-side direction (in the ±X directions) of the insulated circuit substrate 3. The width (in the ±Y directions) of the lead frame 6 may be approximately the same as the widths (in the ±Y directions) of the output electrodes 4a and 5a of the semiconductor chips 4 and 5. In this connection, the shape, length, and width of the lead frame 6 illustrated in FIGS. 1 and 2 are just an example. The lead frame 6 may have a uniform thickness of 0.25 mm or less throughout. The thickness of the lead frame 6 will be described in detail later.

This lead frame 6 includes a first bonding portion 6a (an example of a second portion), a second bonding portion 6b (an example of a first portion), and an inclined portion 6c. In addition, the lead frame 6 has a bonding principal surface 6f that faces the insulated circuit substrate 3. The first bonding portion 6a of the lead frame 6 is bonded to the output electrode 4a of the semiconductor chip 4 via bonding members 9a. In addition, the second bonding portion 6b of the lead frame 6 is bonded to the output electrode 5a of the semiconductor chip 5 via bonding members 9b.

In addition, first protrusions 6a1 (examples of a second protrusion) and second protrusions 6b1 (examples of a first protrusion) are formed in the bonding principal surface 6f in the first bonding portion 6a and second bonding portion 6b of the lead frame 6, respectively. More specifically, in the bonding principal surface 6f of the lead frame 6, the first protrusions 6a1 and second protrusions 6b1 protrude toward the output electrodes 4a and 5a of the semiconductor chips 4 and 5, respectively. The first protrusions 6a1 and second protrusions 6b1 of the lead frame 6 are bonded to the output electrodes 4a and 5a of the semiconductor chips 4 and 5 via the bonding members 9a and 9b, respectively. In this connection, the bonding members 9a and 9b may be made of the same material as the bonding members 8a and 8b. In this connection, the bonding members 9a and 9b may be a sintered metal. In addition, the bonding members 9a and 9b have different heights measured from the front surface of the conductive plate 3b of the insulated circuit substrate 3. This difference in height is denoted by a difference S. The difference S in height is a maximum of approximately 0.5 mm, and is less than 0.5 mm.

In addition, the two first protrusions 6a1 are separate from each other. A temperature detection line is set at the center of the output electrode 4a of the semiconductor chip 4. Therefore, the two separate first protrusions 6a1 are bonded to the output electrode 4a of the semiconductor chip 4 while avoiding the temperature detection line. The two second protrusions 6b1 are separate from each other for the same reason, and are bonded to the semiconductor chip 5 in the same manner.

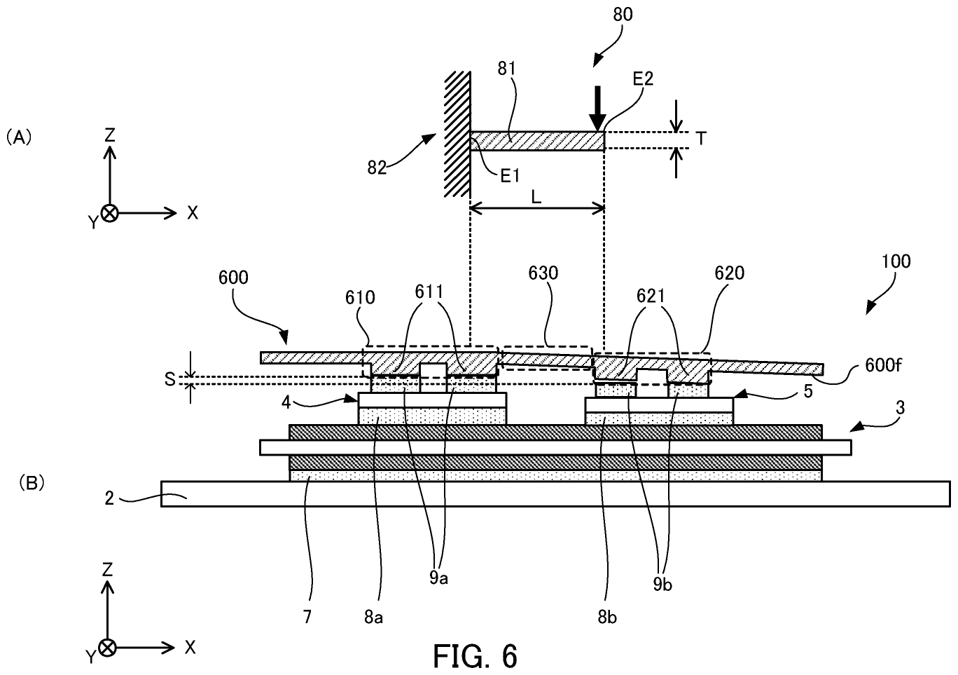

These first protrusions 6a1 and second protrusions 6b1 are formed by, for example, pressing an elongated flat plate from the front surface toward the rear surface. In the case of the pressing process, the surface of the lead frame 6 (i.e., the non-bonding principal surface) opposite to the bonding principal surface 6f may be recessed at positions corresponding to the first protrusions 6a1 and second protrusions 6b1. In the present embodiment, in the first bonding portion 6a and second bonding portion 6b of the lead frame 6, first recesses 6a2 (examples of a second recess) and second recesses 6b2 (examples of a first recess) are formed at positions corresponding to the first protrusions 6a1 and second protrusions 6b1 in the surface opposite to the bonding principal surface 6f. Alternatively, block-shaped members may be bonded at predetermined positions of an elongated flat plate by welding (see FIG. 6 for this shape only). In this case, the surface of the lead frame 6 opposite to the surface having the block-shaped members bonded thereto may be flat.

Provided between the first bonding portion 6a and the second bonding portion 6b of the lead frame 6, the inclined portion 6c is inclined. As described earlier, the front surfaces of the bonding members 9a and 9b have different heights measured from the front surface of the conductive plate 3b of the insulated circuit substrate 3, and this difference in height is denoted by the difference S. Therefore, the first protrusions 6a1 and the second protrusions 6b1 have the difference S in height in the bonding principal surface 6f.

Therefore, in the lead frame 6, the first bonding portion 6a is located higher than the second bonding portion 6b. The inclined portion 6c is inclined so as to connect the first bonding portion 6a and the second bonding portion 6b that differ in height. In addition, the inclined portion 6c is inclined by elastic deformation.

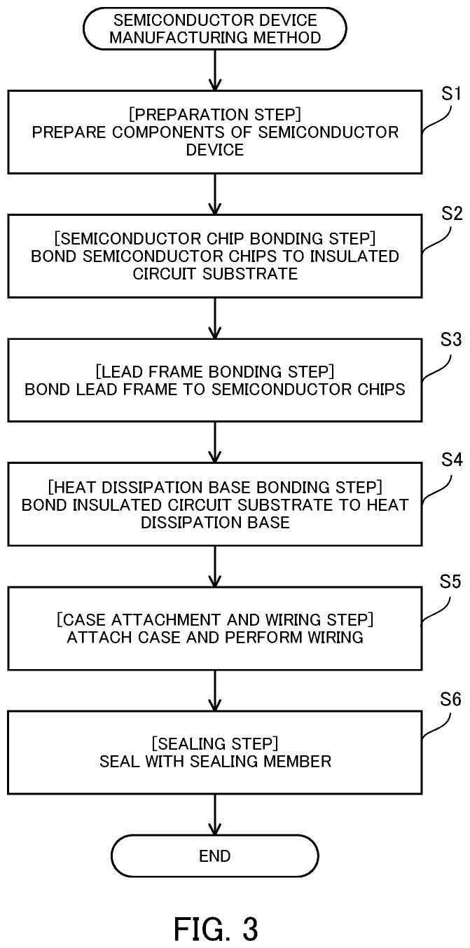

The following describes a method of manufacturing the semiconductor device 1 with reference to FIG. 3. FIG. 3 is a flowchart illustrating a semiconductor device manufacturing method according to the first embodiment. First, a preparation step of preparing components of the semiconductor device 1 is executed (step S1). For example, the components to be prepared include the insulated circuit substrate 3, semiconductor chips 4 and 5, and lead frame 6. Other than these, any components needed for the semiconductor device 1 may be prepared. In addition, manufacturing devices that are used for manufacturing the semiconductor device 1 may be prepared.

Then, a semiconductor chip bonding step of bonding the semiconductor chips 4 and 5 to the insulated circuit substrate 3 may be executed (step S2). The semiconductor chips 4 and 5 are placed on the conductive plate 3b of the insulated circuit substrate 3 via the bonding members 8a and 8b. In the case where the bonding members 8a and 8b are made of a sintered material, heating is conducted while the semiconductor chips 4 and 5 are pressed against the insulated circuit substrate 3. By doing so, the semiconductor chips 4 and 5 are bonded to the conductive plate 3b of the insulated circuit substrate 3 by the sintered bonding members 8a and 8b.

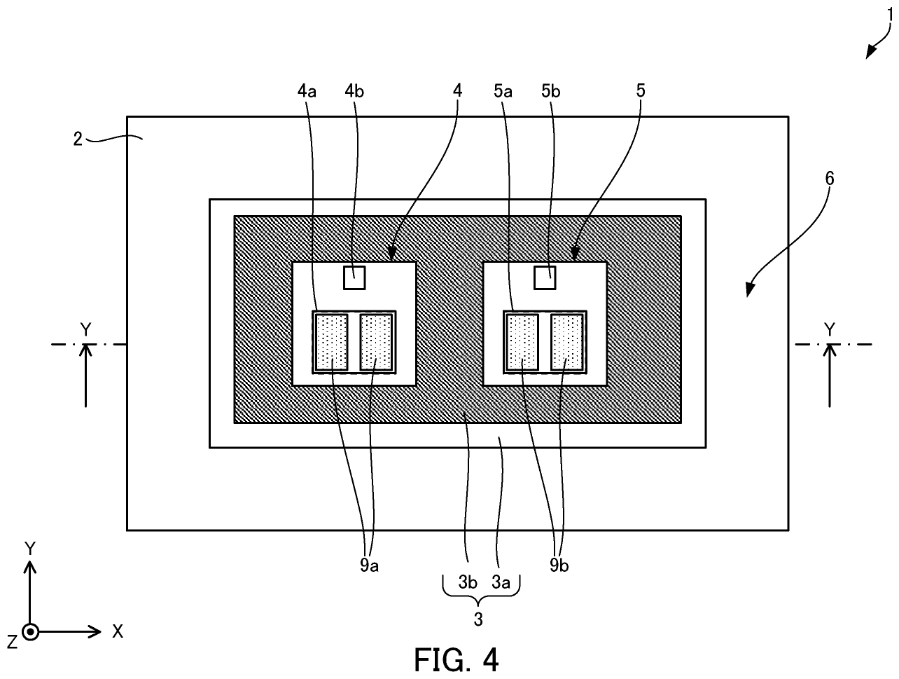

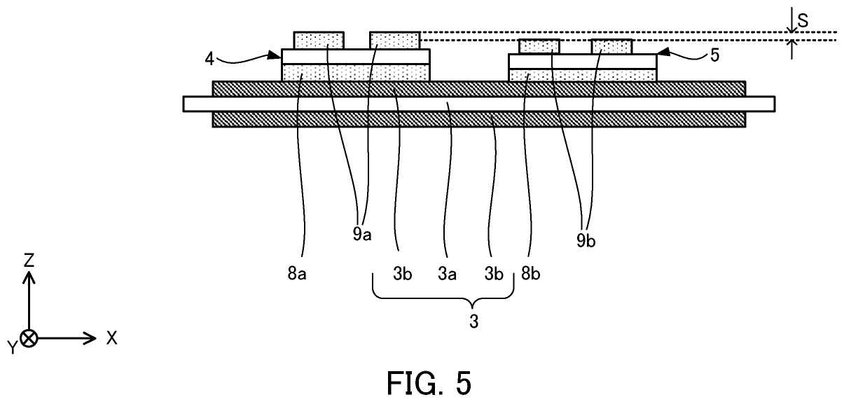

After that, a lead frame bonding step of bonding the lead frame 6 to the semiconductor chips 4 and 5 is executed (step S3). The formation of the bonding members 9a and 9b on the output electrodes 4a and 5a of the semiconductor chips 4 and 5 in the lead frame bonding step will now be described with reference to FIGS. 4 and 5. FIG. 4 is a plan view depicting the semiconductor chip bonding step included in the semiconductor device manufacturing method according to the first embodiment. FIG. 5 is a sectional view depicting the semiconductor chip bonding step included in the semiconductor device manufacturing method according to the first embodiment. In this connection, FIG. 5 is a sectional view taken along a dash-dotted line Y-Y of FIG. 4.

First, the bonding members 9a and bonding members 9b are placed respectively on the output electrodes 4a and 5a of the semiconductor chips 4 and 5, separately in the ±X directions, as illustrated in FIGS. 4 and 5. At this time, the heights of the bonding members 9a measured from the front surface of the conductive plate 3b of the insulated circuit substrate 3 are higher by the difference S than those of the bonding members 9b measured from the front surface of the conductive plate 3b. The first protrusions 6a1 and second protrusions 6b1 of the lead frame 6 are pressed via the bonding members 9a and 9b against the output electrodes 4a and 5a of the semiconductor chips 4 and 5 while the bonding members 9a and 9b are heated. In thus bonded lead frame 6, the first protrusions 6a1 of the first bonding portion 6a are located higher than the second protrusions 6b1 of the second bonding portion 6b, and thus the inclined portion 6c is inclined.

Then, a heat dissipation base bonding step of bonding the insulated circuit substrate 3 to the heat dissipation base 2 via the bonding member 7 is executed (step S4). The insulated circuit substrate 3 obtained in step S3, to which the semiconductor chips 4 and 5 and lead frame 6 have been bonded in order, is bonded to the heat dissipation base 2 via the bonding member 7. Through the above steps, the semiconductor device 1 illustrated in FIGS. 1 and 2 is obtained.

In this connection, the following steps may be executed thereafter. A case attachment and wiring step of attaching a case to the heat dissipation base 2 and performing wiring is executed (step S5). For example, a frame-shaped case that surrounds the open housing space is bonded to the heat dissipation base 2. At this time, the insulated circuit substrate 3 is housed in the housing space. In addition, the semiconductor chips 4 and 5, conductive plate 3b, and terminals included in the case are wired as needed.

Then, a sealing step of sealing the inside of the housing space of the case with a sealing member (step S6). The housing space of the case is filled with the sealing member, which thereby seals, for example, the insulated circuit substrate 3, semiconductor chips 4 and 5, and lead frame 6 inside the housing space. As a result, the semiconductor device 1 including the case is obtained.

The following describes stress that is applied to the lead frame 6 depending on the thickness of the lead frame 6. For describing a result of analyzing the stress, an analysis model will first be described with reference to FIG. 6. FIG. 6 is a sectional view of a semiconductor device according to a reference example. (A) of FIG. 6 is a side view of an analysis model 80, and (B) of FIG. 6 is a side view of a semiconductor device 100 that is an example to which the analysis model 80 is applied.

The analysis model 80 includes a wiring member 81 and a fixing element 82 that fixes one end E1 of the wiring member 81. The wiring member 81 is made of copper as a main component and has a flat plate shape. The one end E1 of the wiring member 81 is fixed by the fixing element 82 and the other end E2 thereof extends in the +X direction with respect to the fixing element 82. The wiring member 81 has a length L (in the ±X directions) of approximately 5 mm and a width (in the ±Y directions) of approximately 10 mm. In this connection, the length L of the wiring member 81 is so set to such a length because it is expected that the distance between elements that are connected with the wiring member 81 will not be less than 5 mm. In addition, the thickness T (in the ±Z directions) of the wiring member 81 is changed appropriately. The other end E2 of this wiring member 81 is pressed and displaced by approximately 0.5 mm in the −Z direction. That is, the other end E2 of the wiring member 81 is displaced in the −Z direction, with a displacement amount of approximately 0.5 mm.

The following describes the semiconductor device 100 to which the analysis model 80 is applied. As illustrated in (B) of FIG. 6, the semiconductor device 100 may include at least a heat dissipation base 2, an insulated circuit substrate 3, semiconductor chips 4 and 5, and a lead frame 600. In this connection, a laminate formed by the heat dissipation base 2, insulated circuit substrate 3, and semiconductor chips 4 and 5 has the same configuration as that provided in the semiconductor device 1 of FIGS. 1 and 2. That is, the heights of the front surfaces of bonding members 9a provided in the semiconductor device 100 measured from the conductive plate 3b of the insulated circuit substrate 3 are higher than those of the front surfaces of bonding members 9b measured from the conductive plate 3b.

The thicknesses of the semiconductor chips 4 and 5 depend on their types. Even in the case where the semiconductor chips 4 and 5 are of the same type, the bonding members 8a and 8b may have different thicknesses, and the bonding members 9a and 9b may have different thicknesses. For this reason, in the semiconductor device 100, the front surfaces of the bonding members 9a and the front surfaces of the bonding members 9b may have different heights. It is recognized that this difference S in height is a maximum of approximately 0.5 mm, and is less than 0.5 mm.

If such a difference in height is somewhat small, a solder when used as the bonding members 8a and 8b and bonding members 9a and 9b may compensate for the difference. In the case where a sintered metal is used to form the bonding members 8a and 8b and bonding members 9a and 9b, however, the difference in height remains. The present embodiment uses a sintered metal as the bonding members 8a and 8b and bonding members 9a and 9b.

The lead frame 600 has an elongated flat plate shape in plan view. The length (in the ±X directions) of the lead frame 600 may be greater than that of the long side in the long-side direction (in the ±X directions) of the insulated circuit substrate 3. The width (in the ±Y directions) of the lead frame 600 may be approximately the same as the widths (in the ±Y directions) of the output electrodes 4a and 5a of the semiconductor chips 4 and 5.

This lead frame 600 includes a first bonding portion 610, a second bonding portion 620, and an inclined portion 630. The lead frame 600 has a bonding principal surface 600f that faces the insulated circuit substrate 3. The first bonding portion 610 of the lead frame 600 is bonded to the output electrode 4a of the semiconductor chip 4 via the bonding members 9a. In addition, the second bonding portion 620 of the lead frame 600 is bonded to the output electrode 5a of the semiconductor chip 5 via the bonding members 9b.

First protrusions 611 and second protrusions 621 are formed on the bonding principal surface 600f in the first and second bonding portions 610 and 620 of the lead frame 600. The first protrusions 611 and second protrusions 621 each have a block shape. The first protrusions 611 and second protrusions 621 are bonded to the output electrodes 4a and 5a of the semiconductor chips 4 and 5 via the bonding members 9a and 9b, respectively. In this connection, the bonding members 9a and 9b are the same as those illustrated in FIGS. 1 and 2.

Provided between the first bonding portion 610 and the second bonding portion 620 of the lead frame 600, the inclined portion 630 is inclined. As described earlier, the heights of the bonding members 9a measured from the front surface of the conductive plate 3b of the insulated circuit substrate 3 are higher than those of the bonding members 9b measured from the front surface of the conductive plate 3b. Accordingly, the inclined portion 630 is inclined in such a manner that the inclined portion 630 is lower on the +X side than on the −X side, as illustrated in (B) of FIG. 6.

The wiring member 81 of the analysis model 80 corresponds to the inclined portion 630 of the lead frame 600. The other end E2 of the wiring member 81 is pressed in the −Z direction, so that the wiring member 81 is inclined in such a manner that the other end E2 on the +X side is lower by approximately 0.5 mm than the one end E1 on the −X side. This is because, as described earlier, the semiconductor device 100 has the difference S in height between the front surfaces of the bonding members 9a and the front surfaces of the bonding members 9b.

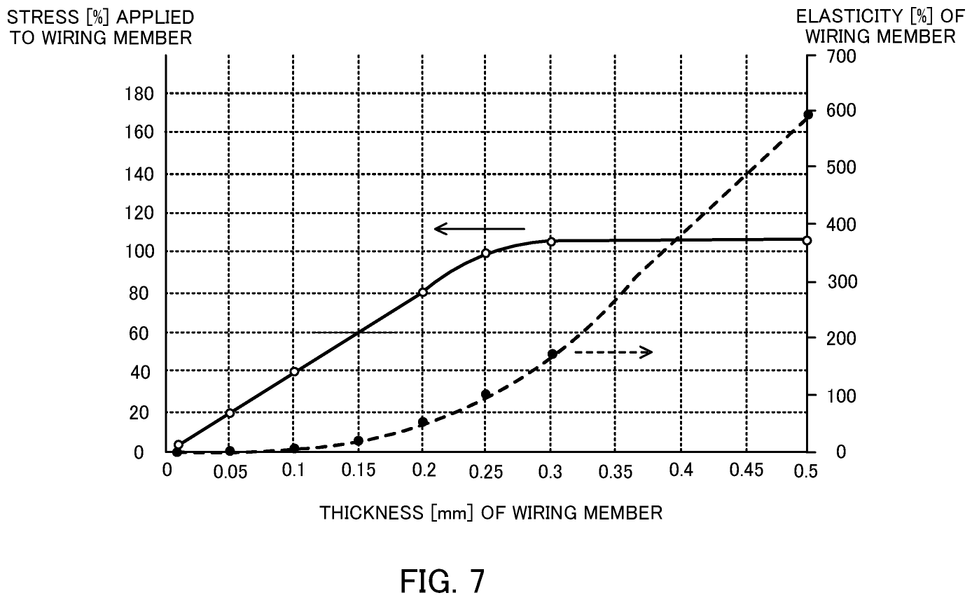

A result of analyzing stress applied to the wiring member 81 and the elasticity of the wiring member 81, which depend on the thickness T of the wiring member 81, will be described with reference to FIG. 7. FIG. 7 is a graph representing stress applied to the lead frame of the reference example and the elasticity of the lead frame with respect to the thickness of the lead frame.

In this connection, the horizontal axis of FIG. 7 represents the thickness [mm] of the wiring member 81, the vertical axis on the left side of FIG. 7 represents stress [%] applied to the wiring member 81, and the vertical axis on the right side of FIG. 7 represents the elasticity [%] of the wiring member 81. In this connection, the stress is normalized with the yield point of the wiring member 81 set at 100%, and the elasticity is normalized with the elasticity at a thickness T of 0.25 mm of the wiring member 81 set at 100%. In addition, the solid line in the graph corresponds to the vertical axis on the left side, and the broken line in the graph corresponds to the vertical axis on the right side.

The other end E2 of the wiring member 81 of the analysis model 80 is pressed in the −Z direction such that the other end E2 is displaced by 0.5 mm in the-Z direction. The elasticity of the wiring member 81 increases as the thickness T increases, as seen in the vertical axis on the right side of FIG. 7.

The stress applied to the wiring member 81 increases and reaches the yield point (100%) as the thickness T increases, as seen in the vertical axis on the left side of FIG. 7. The thickness T of the wiring member 81 that reaches the yield point is approximately 0.25 mm. When the thickness T exceeds 0.25 mm, the stress hardly increases and is kept almost constant. That is, the wiring member 81 is subjected to an elastic deformation when the thickness T is less than 0.25 mm, and the wiring member 81 is subjected to a plastic deformation when the thickness T exceeds 0.25 mm.

In the semiconductor device 100 illustrated in (B) of FIG. 6, the bonding members 8a, 8b, 9a, and 9b each have a thickness of approximately 0.1 mm. Assuming that the semiconductor chip 4 is an IGBT and the semiconductor chip 5 is an FWD, the difference in thickness between them is approximately 0.1 mm or less. Therefore, the difference in height measured from the conductive plate 3b of the insulated circuit substrate 3 between the front surfaces of the bonding members 9a and 9b is expected to be approximately 0.5 mm. In this connection, in this analysis, the width (in the ±Y directions) of the wiring member 81 has little effect on the stress applied to the wiring member 81 and the elasticity of the wiring member 81.

According to the graph of FIG. 7, the elasticity of the lead frame 600 increases as the thickness T of the lead frame 600 increases. Therefore, in the case where the lead frame 600 is bonded to the output electrodes 4a and 5a of the semiconductor chips 4 and 5 located at different heights, the lead frame 600 is more likely to be detached from the output electrodes 4a and 5a (bonding members 9a and 9b) as the thickness T increases.

In addition, in the case where the lead frame 600 has a thickness of approximately 1 mm, the lead frame 600 is subjected to a plastic deformation without affecting the electrical conductivity. However, in the case where the lead frame 600 is thinner and is bent by plastic deformation, the lead frame 600 has a smaller cross-sectional area and a higher electrical resistance. In other words, in this case, the lead frame 600 heats up due to current concentration, which results in deterioration.

To deal with this, the above-described semiconductor device 1 includes the semiconductor chips 4 and 5 and the lead frame 6. The semiconductor chip 4 has the output electrode 4a on the front surface thereof. The semiconductor chip 5 is disposed apart from the semiconductor chip 4 in plan view and has the output electrode 5a on the front surface thereof. The lead frame 6 has a flat plate shape, is provided above the front surfaces of the semiconductor chips 4 and 5, and includes the first bonding portion 6a and second bonding portion 6b that are bonded respectively to the output electrodes 4a and 5a of the semiconductor chips 4 and 5. In addition, in side view, the output electrodes 4a and 5a of the semiconductor chips 4 and 5 have different heights, and the lead frame 6 includes the inclined portion 6c between the first bonding portion 6a and the second bonding portion 6b. The inclined portion 6c is inclined by elastic deformation such that the first bonding portion 6a is located higher than the second bonding portion 6b. Therefore, in the case where the lead frame 6 is inclined due to the heights of the semiconductor chips 4 and 5, the concentration of current on the inclined portion 6c is reduced, which reduces the generation of heat and thus prevents the deterioration. Furthermore, the lead frame 6 has low elasticity, which reduces the risk of detaching the lead frame 6 from the output electrodes 4a and 5a of the semiconductor chips 4 and 5 and thus improves the connectivity of the lead frame 6 to the output electrodes 4a and 5a of the semiconductor chips 4 and 5. As a result, a reduction in the reliability of the semiconductor device 1 is prevented. Especially, in order that the lead frame 6 is subjected to an elastic deformation and has low elasticity, the thickness T of the lead frame 6 is preferably set to 0.25 mm or less.

### Second Embodiment

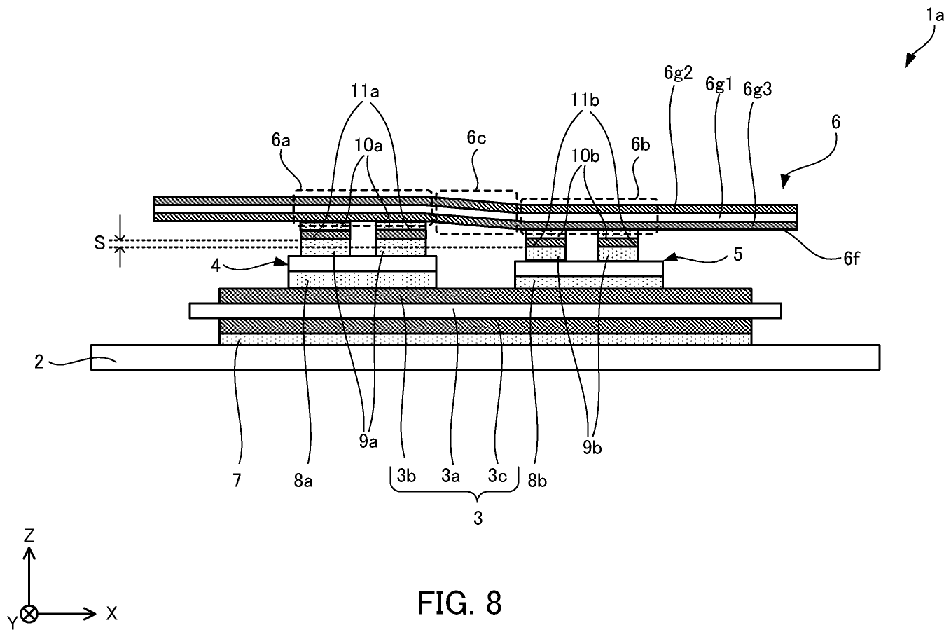

In a second embodiment, a semiconductor device including a lead frame that is different from that used in the first embodiment will be described with reference to FIG. 8. FIG. 8 is a sectional view of a semiconductor device according to the second embodiment. Although a plan view of the semiconductor device 1a of FIG. 8 is not illustrated, FIG. 8 is a sectional view of a part corresponding to the dash-dotted line Y-Y of FIG. 1.

The semiconductor device 1a of the second embodiment includes a heat dissipation base 2, an insulated circuit substrate 3, and semiconductor chips 4 and 5, which are the same as those provided in the semiconductor device 1 of the first embodiment. Bonding members 7, 8a, and 8b bonding these units are also the same as those used in the first embodiment.

The lead frame 6 provided in the semiconductor device 1a includes a plurality of conductive layers and an insulating layer(s) between the plurality of conductive layers. In this case, the total thickness of the plurality of conductive layers is 0.25 mm or less. In this embodiment, the lead frame 6 includes two conductive layers 6g2 and 6g3 and an insulating layer 6g1 between the conductive layers 6g2 and 6g3. The total thickness of the conductive layers 6g2 and 6g3 is 0.25 mm or less.

This lead frame 6 as well includes a first bonding portion 6a, a second bonding portion 6b, and an inclined portion 6c. In addition, the lead frame 6 has a bonding principal surface 6f that faces the insulated circuit substrate 3. The length (in the ±X directions) and width (in the ±Y directions) of the lead frame 6 are the same as those described in the first embodiment. The thickness of the lead frame 6 of the second embodiment may be set such that the total thickness of the conductive layers 6g2 and 6g3 is 0.25 mm or less.

The first bonding portion 6a of the lead frame 6 is bonded to the output electrode 4a of the semiconductor chip 4 via bonding members 11a. The second bonding portion 6b of the lead frame 6 is bonded to the output electrode 5a of the semiconductor chip 5 via bonding members 11b.

The bonding principal surface 6f in the first bonding portion 6a of the lead frame 6 is bonded to the output electrode 4a of the semiconductor chip 4 via a laminate of a bonding member 9a, a conductive plate 10a, and a bonding member 11a. Likewise, the bonding principal surface 6f in the second bonding portion 6b of the lead frame 6 is bonded to the output electrode 5a of the semiconductor chip 5 via a laminate of a bonding member 9b, a conductive plate 10b, and a bonding member 11b. In this connection, in plan view, the conductive plates 10a and 10b have the same size as the bonding members 9a and 9b and each have a flat plate shape. The conductive plates 10a and 10b are made of a metal with high electrical conductivity. Examples of the metal here include copper, aluminum, and an alloy containing at least one of these. Plating may be performed on the surfaces of the conductive plates 10a and 10b to improve their corrosion resistance. Examples of the plating material used here include nickel, a nickel-phosphorus alloy, and a nickel-boron alloy. The bonding members 11a and 11b may be made of the same material as the bonding members 9a and 9b.

In addition, in the semiconductor device 1a as well, the front surfaces of the bonding members 11a and 11b have different heights measured from the front surface of the conductive plate 3b of the insulated circuit substrate 3. In the second embodiment, the front surfaces of the bonding members 11a are located higher than those of the bonding members 11b.

Provided between the first bonding portion 6a and the second bonding portion 6b of the lead frame 6, the inclined portion 6c is inclined. In the present embodiment, since the first bonding portion 6a is located higher than the second bonding portion 6b, the inclined portion 6c is higher on the −X side than on the +X side. In this case, the total thickness of the conductive layers 6g2 and 6g3 of the lead frame 6 is 0.25 mm or less. In this case, the inclined portion 6c of the lead frame 6 is subjected to an elastic deformation.

Therefore, even in the case where the lead frame 6 of the second embodiment is inclined due to the heights of the semiconductor chips 4 and 5, the concentration of current on the inclined portion 6c is reduced, which reduces the generation of heat and prevents the deterioration. Furthermore, the lead frame 6 has low elasticity, which reduces the risk of detaching the lead frame 6 from the output electrodes 4a and 5a of the semiconductor chips 4 and 5 and thus improves the connectivity of the lead frame 6 to the output electrodes 4a and 5a of the semiconductor chips 4 and 5. As a result, a reduction in the reliability of the semiconductor device 1a is prevented.

### Third Embodiment

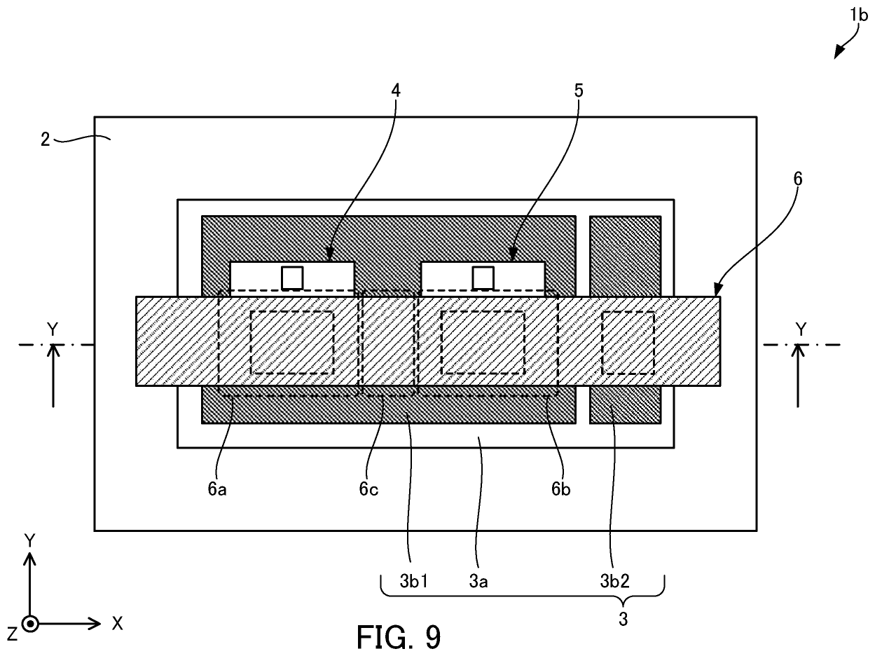

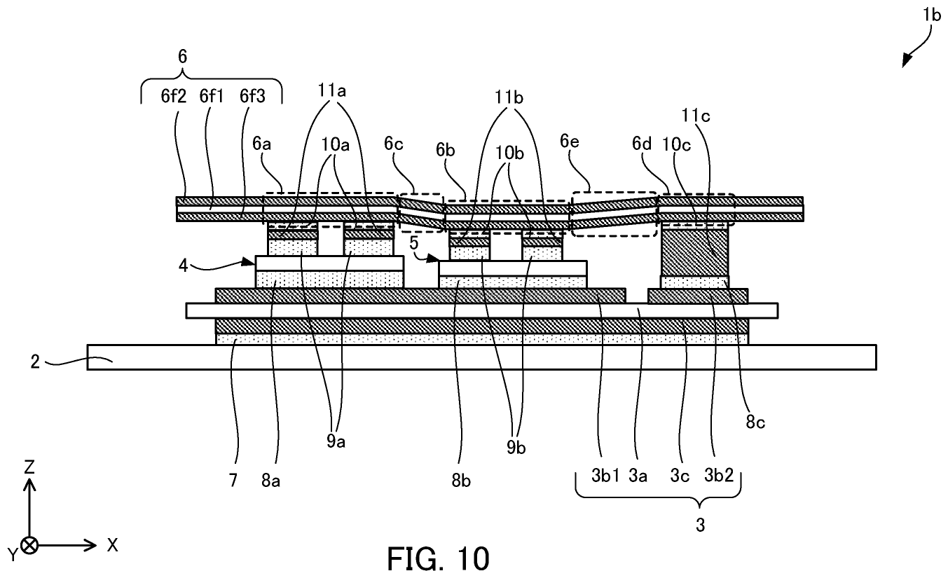

In a third embodiment, a semiconductor device in which the lead frame 6 of the second embodiment is bonded at three positions will be described with reference to FIGS. 9 and 10. FIG. 9 is a plan view of a semiconductor device according to the third embodiment. FIG. 10 is a sectional view of the semiconductor device according to the third embodiment. In this connection, FIG. 10 is a sectional view taken along a dash-dotted line Y-Y of FIG. 9.

The semiconductor device 1b of the third embodiment includes a heat dissipation base 2, an insulated circuit substrate 3, semiconductor chips 4 and 5, and a lead frame 6, which are the same as those provided in the second embodiment. In the insulated circuit substrate 3 of the third embodiment, however, conductive plates 3b1 and 3b2 are formed on the front surface of the insulating plate 3a. The semiconductor chips 4 and 5 are bonded to the conductive plate 3b1 via bonding members 8a and 8b. In the third embodiment, a conductive block 10c is provided on the conductive plate 3b2 via a bonding member 8c. In this connection, the output electrodes 4a and 5a of the semiconductor chips 4 and 5 and the conductive block 10c are linearly arranged in the ±X directions in plan view.

The conductive block 10c is made of a metal with high electrical conductivity. Examples of the metal here include copper, aluminum, and an alloy containing at least one of these. In addition, plating may be performed on the surface of the conductive block 10c to improve its corrosion resistance. Examples of the plating material used here include nickel, a nickel-phosphorus alloy, and a nickel-boron alloy. The height of the conductive block 10c measured from the front surface of the conductive plate 3b2 of the insulated circuit substrate 3 is higher than the heights of the bonding members 11b measured from the front surface of the conductive plate 3b1 of the insulated circuit substrate 3. In this connection, the bonding member 8c may be made of the same material as the bonding members 8a and 8b.

The lead frame 6 of the third embodiment includes a third bonding portion 6d and an inclined portion 6e in addition to a first bonding portion 6a, a second bonding portion 6b, and an inclined portion 6c. The third bonding portion 6d of the lead frame 6 is bonded to the conductive block 10c via a bonding member 11c.

Provided between the second bonding portion 6b and the third bonding portion 6d of the lead frame 6, the inclined portion 6e is inclined. In the present embodiment, since the third bonding portion 6d is located higher than the second bonding portion 6b, the inclined portion 6e is higher on the +X side than on the −X side. As described earlier, the total thickness of conductive layers 6f2 and 6f3 of the lead frame 6 is 0.25 mm or less. In this case, the inclined portion 6e of the lead frame 6 as well is subjected to an elastic deformation. In this connection, the bonding member 11c may be made of the same material as the bonding members 11a and 11b.

Therefore, even in the case where the lead frame 6 of the third embodiment is inclined due to the difference in height between the semiconductor chip 5 and the conductive block 10c, concentration of current on the inclined portion 6e is reduced, which reduces the generation of heat and prevents the deterioration. In addition, the lead frame 6 has low elasticity, which reduces the risk of detaching the lead frame 6 from the output electrodes 4a and 5a of the semiconductor chips 4 and 5 and the conductive block 10c and thus improves the connectivity of the lead frame 6 to the output electrodes 4a and 5a of the semiconductor chips 4 and 5 and the conductive block 10c. As a result, a reduction in the reliability of the semiconductor device 1b is prevented.

### Fourth Embodiment

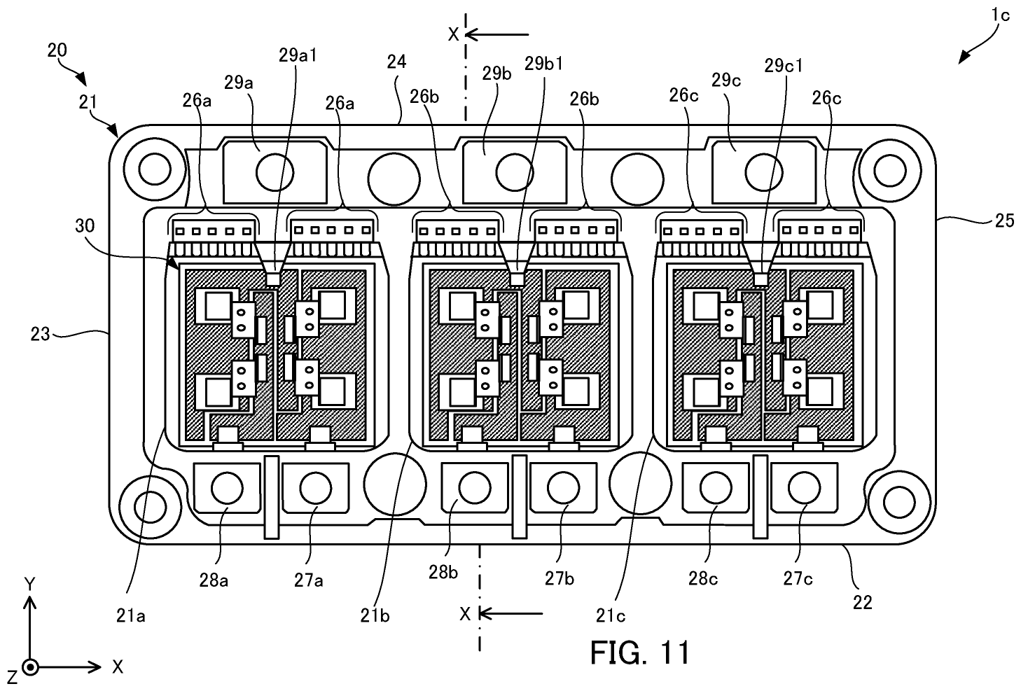

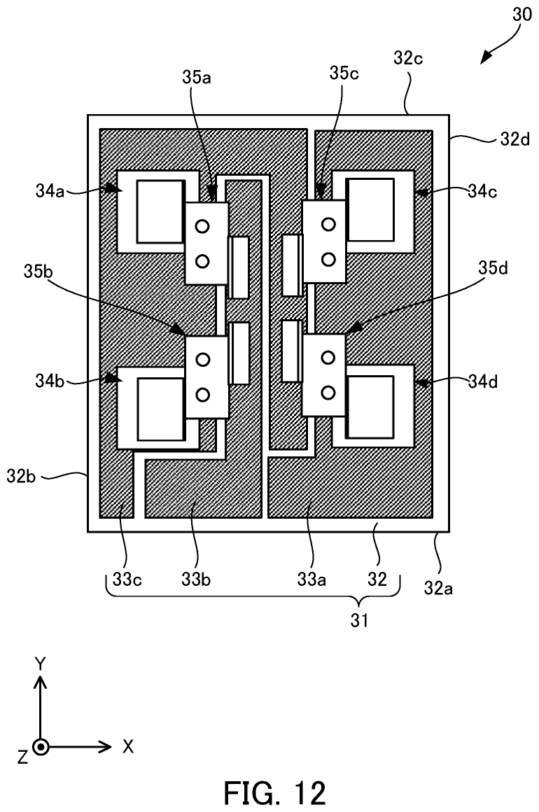

In a fourth embodiment, a semiconductor device in which one end of a lead frame 6 is fixed to a case and the other end thereof is connected to a conductive element will be described with reference to FIGS. 11 and 12. FIG. 11 is a plan view of a semiconductor device according to the fourth embodiment. FIG. 12 is a plan view of a semiconductor unit provided in the semiconductor device according to the fourth embodiment.

As illustrated in FIG. 11, the semiconductor device 1c includes semiconductor units 30 and a case 20 housing the semiconductor units 30. In this connection, FIG. 11 exemplifies a case where the case 20 has three housing spaces 21a to 21c and a semiconductor unit 30 is housed in each housing space 21a to 21c. The illustration of a sealing member sealing the housing spaces 21a to 21c housing the semiconductor units 30 is omitted.

Each semiconductor unit 30 includes an insulated circuit substrate 31 (an example of a substrate), semiconductor chips 34a to 34d, and lead frames 35a to 35d, as illustrated in FIG. 12. The insulated circuit substrate 31 is rectangular in plan view. The insulated circuit substrate 31 includes an insulating plate 32, a plurality of conductive layers (examples of a wiring plate) formed on the front surface of the insulating plate 32, and a metal plate (not illustrated) formed on the rear surface of the insulating plate 32. The plurality of conductive layers include a positive electrode conductive layer 33a, a negative electrode conductive layer 33b, and an output conductive layer 33c. In the following, these conductive layers are collectively referred to as conductive layers simply when the distinction among them is not needed. In plan view, the outline of the plurality of conductive layers and the outline of the metal plate are smaller than the outline of the insulating plate 32, and the plurality of conductive layers and the metal plate are formed inside the insulating plate 32. The shapes, quantity, and sizes of the plurality of conductive layers illustrated in FIG. 12 are just an example.

The insulating plate 32, the plurality of conductive layers, and the metal plate are formed in the same manner as the insulating plate 3a, conductive plate 3b, and metal plate 3c of the first embodiment. As described earlier, the plurality of conductive layers include the positive electrode conductive layer 33a, negative electrode conductive layer 33b, and output conductive layer 33c. The plurality of conductive layers are formed on the entire surface of the insulating plate 32 except the edge thereof. In plan view, the edges of the plurality of conductive layers facing the outer periphery of the insulating plate 32 are preferably aligned with the edges of the metal plate facing the outer periphery of the insulating plate 32.

In plan view, the positive electrode conductive layer 33a included in the plurality of conductive layers has a reversed L shape and is formed adjacent to a long side 32d of the insulating plate 32 so as to face the long side 32d and short side 32a of the insulating plate 32. In this connection, semiconductor chips 34d and 34c are bonded to the positive electrode conductive layer 33a such that the semiconductor chips 34d and 34c are linearly arranged in the +Y direction.

In plan view, the negative electrode conductive layer 33b included in the plurality of conductive layers has a reversed L shape and is formed next to the positive electrode conductive layer 33a on the −X side thereof so as to face the short side 32a of the insulating plate 32.

In plan view, the output conductive layer 33c included in the plurality of conductive layers has an approximately U-shape and is formed so as to face a long side 32b and short side 32c of the insulating plate 32 and surround the negative electrode conductive layer 33b. In this connection, semiconductor chips 34b and 34a are bonded to the output conductive layer 33c such that the semiconductor chips 34b and 34a are linearly arranged in the +Y direction.

As the insulated circuit substrate 31 configured as above, a DCB substrate or an AMB substrate may be used, for example. The insulated circuit substrate 31 transfers heat generated by the semiconductor chips 34a to 34d via the output conductive layer 33c or positive electrode conductive layer 33a, the insulating plate 32, and the metal plate to the rear surface of the insulated circuit substrate 31 and then dissipates the heat.

The semiconductor chips 34a to 34d may be the same as the semiconductor chips 4 and 5 of the first embodiment. In addition, the semiconductor chips 34a and 34b are bonded to the output conductive layer 33c such that their control electrodes, which are not illustrated, face the long side 32b, and the semiconductor chips 34c and 34d are bonded to the positive electrode conductive layer 33a such that their control electrodes, which are not illustrated, face the long side 32d.

In the present embodiment, the semiconductor chips 34a to 34d are bonded to the output conductive layer 33c and positive electrode conductive layer 33a via bonding members. The bonding members here may be the same as the bonding members 8a and 8b of the first embodiment.

The lead frames 35a to 35d are made of a metal with high electrical conductivity. Examples of the metal here include copper, aluminum, and an alloy containing at least one of these. In addition, plating may be performed on the surfaces of the lead frames 35a to 35d to improve their corrosion resistance. Examples of the plating material used here include nickel, a nickel-phosphorus alloy, and a nickel-boron alloy. Each lead frame 35a to 35d may have a uniform thickness throughout.

The lead frame 35c electrically connects the output electrode of the semiconductor chip 34c and the output conductive layer 33c, and the lead frame 35d electrically connects the output electrode of the semiconductor chip 34d and the output conductive layer 33c. The lead frame 35a electrically connects the output electrode of the semiconductor chip 34a and the negative electrode conductive layer 33b, and the lead frame 35b electrically connects the output electrode of the semiconductor chip 34b and the negative electrode conductive layer 33b. These lead frames 35a to 35d are bonded to the output electrodes of the semiconductor chips 34a to 34d via one of the above-described bonding members. The lead frames 35a to 35d are bonded to the conductive layers using one of the above-described bonding members. Alternatively, the lead frames 35a to 35d may be bonded to the conductive layers by ultrasonic bonding.

The case 20 includes a frame 21, and P terminals 27a to 27c, N terminals 28a to 28c, and U, V, and W terminals 29a to 29c integrally formed with the frame 21, as illustrated in FIG. 11.

The frame 21 is rectangular in plan view and has a frame shape. The frame 21 has a long side portion 22, a short side portion 23, a long side portion 24, and a short side portion 25 in order on its four sides thereof. The center of the frame 21 surrounded by the long side portion 22, short side portion 23, long side portion 24, and short side portion 25 is divided into three housing spaces 21a to 21c.

The housing spaces 21a to 21c are arranged in a line along the long side portions 22 and 24. Each housing space 21a to 21c is rectangular in plan view. A semiconductor unit 30 is housed in each housing space 21a to 21c. The semiconductor unit 30 housed in each housing space 21a to 21c is located such that the semiconductor chips 34a and 34c are located on the side closer to the long side portion 24 and the semiconductor chips 34b and 34d are located on the side closer to the long side portion 22.

The housing spaces 21a to 21c are filled with a sealing member, so that the semiconductor units 30 are sealed with the sealing member. The sealing member may be a thermosetting resin. For example, the thermosetting resin is an epoxy resin, a phenolic resin, a maleimide resin, or a polyester resin, and is preferably an epoxy resin. In addition, the sealing member may contain a filler. The filler is insulating ceramics with high thermal conductivity. Examples of the filler include silicon oxide, aluminum oxide, boron nitride, and aluminum nitride. The filler accounts for 10 vol % or more and 70 vol % or less of the sealing member.

In the case 20, input terminals are arranged at the long side portion 22. The input terminals are the P terminals 27a to 27c and N terminals 28a to 28c provided along the long side portion 22. The external end portions (external connection portions) of the P terminals 27a to 27c and N terminals 28a to 28c are arranged in the +X direction on the front surface of the long side portion 22. The internal end portions (internal connection portions) of the P terminals 27a to 27c and N terminals 28a to 28c are exposed from the inner wall of the long side portion 22 and extend toward the long side portion 24 in the housing spaces 21a to 21c. These internal end portions are electrically connected to conductive layers of the insulated circuit substrate 31 of the semiconductor unit 30 inside the housing spaces 21a to 21c. In this connection, the connections of the internal end portions of the P terminals 27a to 27c and N terminals 28a to 28c will be described in detail later.

In addition, in the case 20, output terminals are arranged at the long side portion 24 located on the side of the housing spaces 21a to 21c opposite to the above-described input terminals. More specifically, the output terminals are the U, V, and W terminals 29a to 29c provided along the long side portion 24. The external end portions (external connection portions) of the U, V, and W terminals 29a to 29c are arranged in the +X direction on the front surface of the long side portion 24. Internal connection portions 29a1 to 29c1 that are the internal end portions of the U, V, and W terminals 29a to 29c are exposed from the inner wall of the long side portion 24 and extend toward the long side portion 22 in the housing spaces 21a to 21c.

In addition, in the case 20, control terminals 26a to 26c are provided on the inner wall of the long side portion 24 facing the housing spaces 21a to 21c. For example, the control terminals 26a are provided on both sides of the internal connection portion 29a1 of the U terminal 29a on the inner wall of the long side portion 24 facing the housing space 21a. The top ends of the control terminals 26a extend in the +Z direction. The bottom ends of the control terminals 26a are exposed from the long side portion 24 toward the housing space 21a and are connected directly to the control electrodes of the semiconductor chips 34a, 34b, 34c, and 34d of the semiconductor unit 30 housed in the housing space 21a with wires. A control signal input to the control terminals 26a is input to the control electrodes of the semiconductor chips 34a, 34b, 34c, and 34d through the wires. Likewise, the control terminals 26b are provided on both sides of the internal connection portion 29b1 of the V terminal 29b on the inner wall of the long side portion 24 facing the housing space 21b, and control terminals 26c are provided on both sides of the internal connection portion 29c1 of the W terminal 29c on the inner wall of the long side portion 24 facing the housing space 21c.

The P terminals 27a to 27c, N terminals 28a to 28c, U, V, and W terminals 29a to 29c, and control terminals 26a to 26c are made of a metal with high electrical conductivity. Examples of the metal here include copper, aluminum, and an alloy containing at least one of these. In addition, plating may be performed on the surfaces of these terminals to improve their corrosion resistance. Examples of the plating material used here include nickel, a nickel-phosphorus alloy, and a nickel-boron alloy.

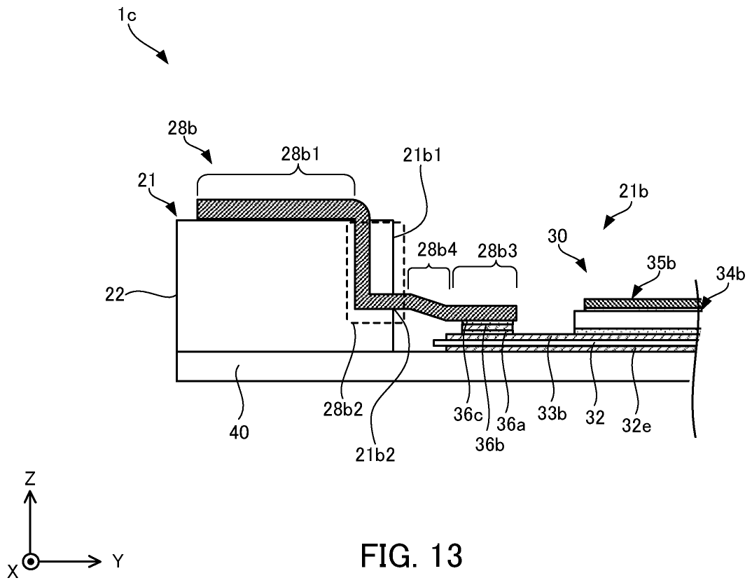

In this connection, a heat dissipation base 40 (see FIG. 13) that has approximately the same size as the case 20 is provided on the rear surface of the case 20. The heat dissipation base 40 has the same configuration as the heat dissipation base 2 of the first embodiment. The semiconductor units 30 are provided on the heat dissipation base 40, and the case 20 is disposed so that the semiconductor units 30 are housed in the housing spaces 21a, 21b, and 21c.

The following describes the bonding of the internal end portions (internal connection portions) of the P terminals 27a to 27c and N terminals 28a to 28c (examples of the wiring member) to the conductive layers of the insulated circuit substrate 31 with reference to FIG. 13. FIG. 13 is a sectional view illustrating a main part of the semiconductor device according to the fourth embodiment. In this connection, FIG. 13 illustrates a main part of a sectional view taken along a dash-dotted line X-X of FIG. 11. The N terminal 28b out of the P terminals 27a to 27c and N terminals 28a to 28c will be described as an example. The same applies to the other terminals.

The N terminal 28b is integrally formed with the frame 21. The N terminal 28b has an approximately uniform thickness of 0.25 mm or less throughout. The N terminal 28b includes an external connection portion 28b1 (an example of a connection end portion), an intermediate portion 28b2 (an example of the second portion), an internal connection portion 28b3 (an example of the first portion), and an inclined portion 28b4 (an example of an inclined portion). The external connection portion 28b1 of the N terminal 28b is exposed from the front surface of the frame 21 of the case 20.

The intermediate portion 28b2 is integrally connected to the external connection portion 28b1. The intermediate portion 28b2 passes from the front surface of the frame 21 through the inside of the frame 21 and then projects from a fixing position (i.e., the fixing region) 21b2 of the inner wall 21b1 (an example of an inner wall surface) that is an outside surface of the frame 21. In side view, the intermediate portion 28b2 has an L shape inside the frame 21, for example. The portion projecting from the fixing position 21b2 is located above (in +Z direction) the front surface of a bonding member 36c to be described later.

The internal connection portion 28b3 is electrically connected to the negative electrode conductive layer 33b of the insulated circuit substrate 31 via a laminate of the bonding member 36a, a conductive plate 36b, and the bonding member 36c. That is, the internal connection portion 28b3 is bonded to the bonding member 36c. In this connection, the conductive plate 36b has a flat plate shape with the same size as the bonding members 36a and 36c in plan view. The conductive plate 36b may be made of the same material as the conductive plates 10a and 10b of the second embodiment. The bonding members 36a and 36c may be made of the same material as the bonding members 11a and 11b.

This semiconductor device 1c includes the bonding member 36c connected to the conductive layer, the frame 21 (fixing element) provided apart from the bonding member 36c in plan view, and the N terminal 28b that has a flat plate shape, is provided above the front surface of the bonding member 36c, and includes the internal connection portion 28b3 bonded to the bonding member 36c and the intermediate portion 28b2 fixed to the frame 21. At this time, in side view, the front surface of the bonding member 36c and a portion of the intermediate portion 28b2 of the N terminal 28b projecting from the fixing position 21b2 of the frame 21 have different heights, and the N terminal 28b includes the inclined portion 28b4 that is provided between the internal connection portion 28b3 and the intermediate portion 28b2 and is inclined by elastic deformation such that the internal connection portion 28b3 is located lower or higher than the portion of the intermediate portion 28b2 projecting from the fixing position 21b2. In the present embodiment, since the portion of the intermediate portion 28b2 projecting from the fixing position 21b2 is located higher than the internal connection portion 28b3, the inclined portion 28b4 is higher on the −Y side than on the +Y side. As described earlier, the N terminal 28b has a thickness of 0.25 mm or less.

Therefore, even in the case where the N terminal 28b of the fourth embodiment is inclined due to the difference in height between the portion projecting from the fixing position 21b2 of the frame 21 and the internal connection portion 28b3, the concentration of current on the inclined portion 28b4 is prevented, which reduces the generation of heat and thus prevents the deterioration. In addition, the N terminal 28b has low elasticity, which reduces the risk of detaching the N terminal 28b from the bonding member 36c (conductive layer) and thus improves the connectivity of the N terminal 28b to the bonding member 36c. As a result, a reduction in the reliability of the semiconductor device 1c is prevented.

An electronic device configured as above has improved connectivity between a wiring member and a conductive element and thus prevents a reduction in reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic device, comprising:
a conductive element having a conductive region on a front surface thereof;
a fixing element having a fixing region on an outside surface thereof, the fixing element being located apart from the conductive element in a plan view of the electronic device; and
a wiring member having a flat plate shape, the wiring member including:
a first portion bonded to the conductive region of the conductive element,
a second portion fixed to the fixing region of the fixing element, and
an inclined portion between the first portion and the second portion, the inclined portion being elastically deformable, wherein
in a side view of the electronic device, the conductive region of the conductive element and the fixing region of the fixing element are at different heights in a thickness direction of the electronic device.

2. The electronic device according to claim 1, wherein:
the conductive element is a first semiconductor chip having a first upper electrode in the conductive region;
the fixing element is a second semiconductor chip having a second upper electrode in the fixing region on a front surface thereof, the front surface being the outside surface;
the electronic device further includes:
a conductive metal element having a conductive principal surface,
a first bonding member, via which a rear surface of the first semiconductor chip is bonded to the conductive principal surface, and
a second bonding member, via which a rear surface of the second semiconductor chip is bonded to the conductive principal surface;
the first portion of the wiring member is bonded to the first upper electrode, and the second portion of the wiring member is bonded to the second upper electrode;
in the thickness direction of the electronic device, a first height, which is a height of the first upper electrode of the first semiconductor chip measured from the conductive principal surface, is lower than a second height that is a height of the second upper electrode of the second semiconductor chip measured from the conductive principal surface; and
the inclined portion of the wiring member has a thickness of 0.25 mm or less.

3. The electronic device according to claim 2, wherein:
the wiring member has a bonding principal surface facing the conductive principal surface; and
the wiring member includes:
a first protrusion on the bonding principal surface in the first portion, the first protrusion protruding toward the first upper electrode and being bonded to the first upper electrode, and
a second protrusion on the bonding principal surface in the second portion, the second protrusion protruding toward the second upper electrode and being bonded to the second upper electrode.

4. The electronic device according to claim 3, wherein
the wiring member further has a non-bonding principal surface opposite to the bonding principal surface; and
the wiring member further includes:
a first recess formed in the non-bonding principal surface at a position corresponding to the first protrusion, and
a second recess formed in the non-bonding principal surface at a position corresponding to the second protrusion.

5. The electronic device according to claim 2, wherein:
the wiring member includes a plurality of conductive layers;
the plurality of conductive layers have a total thickness of 0.25 mm or less; and
the wiring member further includes an insulating layer between two of the plurality of conductive layers.

6. The electronic device according to claim 2, wherein the first semiconductor chip is equal in thickness to the second semiconductor chip.

7. The electronic device according to claim 6, wherein the first bonding member is thinner than the second bonding member.

8. The electronic device according to claim 2, wherein the first semiconductor chip is thinner than the second semiconductor chip.

9. The electronic device according to claim 2, wherein the first bonding member and the second bonding member are made of a sintered material.

10. The electronic device according to claim 1, wherein a distance between the first portion and the second portion is greater than 5 mm in the plan view of the electronic device.

11. The electronic device according to claim 1, wherein the wiring member contains copper or a copper alloy.

12. The electronic device according to claim 1, further comprising a substrate having a wiring plate on a front surface thereof, the conductive element being bonded to the wiring plate, wherein
the fixing element is a frame-shaped case having an inner wall surface surrounding an open housing space, the inner wall surface being the outside surface thereof, the housing space housing the substrate,
the wiring member includes a connection end portion at a side of the second portion opposite to the first portion, the connection end portion being exposed from the case, the second portion being located inside the case, the first portion extending from the fixing region of the inner wall surface of the case toward the housing space and being bonded to the conductive region of the conductive element,
a first height, which is a height of the conductive region of the conductive element measured from a rear surface of the substrate, is lower than a second height, which is a height of the fixing region measured from the rear surface of the substrate, and
the inclined portion of the wiring member has a thickness of 0.25 mm or less.
